(19) United States
(12) Patent Application Publication
(10) Pub. No.: US 2014/0134797 A1
(43) Pub. Date: May 15, 2014

(54) METHOD FOR FABRICATING SEMICONDUCTOR PACKAGE

(71) Applicant: Siliconware Precision Industries Co., Ltd., Taichung (TW)

(72) Inventors: Chieh-Yuan Chi, Taichung (TW); Jung-Pang Huang, Taichung (TW); Yan-Heng Chen, Taichung (TW); Hsi-Chang Hsu, Taichung (TW); Chiang-Cheng Chang, Taichung (TW); Shih-Kuang Chiu, Taichung (TW)

(73) Assignee: SILICONWARE PRECISION INDUSTRIES CO., LTD., Taichung (TW)

(21) Appl. No.: 14/013,512

(22) Filed: Aug. 29, 2013

(30) Foreign Application Priority Data
Nov. 13, 2012 (TW) 101142157
May 7, 2013 (TW) 102116165

(51) Int. Cl. H01L 21/56

(52) U.S. Cl. CPC H01L 21/561
USPC 438/107

(57) ABSTRACT

A method for fabricating a semiconductor package is disclosed, which includes the steps of: providing a carrier having a release layer and an adhesive layer sequentially formed thereon; disposing a plurality of semiconductor chips on the adhesive layer; forming an encapsulant on the adhesive layer for encapsulating the semiconductor chips; disposing a substrate on the encapsulant; exposing the release layer to light through the carrier so as to remove the release layer and the carrier; and then removing the adhesive layer, thereby effectively preventing the semiconductor chips from being exposed to light so as to avoid any photo damage to the semiconductor chips.

### BACKGROUND OF THE INVENTION

1. Field of the Invention

The present invention relates to methods for fabricating semiconductor packages, and, more particularly, to a method for fabricating a semiconductor package that protects semiconductor chips from being damaged by light.

2. Description of Related Art

Currently, there are various types of semiconductor packages available in the market by various manufacturers. As semiconductor chips tend to become miniaturized nowadays, semiconductor processing technologies are required to be continuously improved so as to facilitate fabrication of lighter, thinner, shorter, and smaller electronic products.

FIGS. 1A to 1E are schematic cross-sectional views illustrating a method for fabricating a semiconductor package as disclosed by U.S. Pat. No. 7,202,107.

Referring to FIG. 1A, a carrier 10 is provided and an adhesive layer 11 made of a thermal release tape, for example, is formed on the carrier 10.

Referring to FIG. 1B, a plurality of semiconductor chips 12 are attached to the adhesive layer 11.

Referring to FIG. 1C, an encapsulant 13 is formed on the adhesive layer 11 by molding for encapsulating the semiconductor chips 12.

Referring to FIG. 1D, the carrier 10 and the adhesive layer 11 are removed by heating.

Referring to FIG. 1E, a circuit layer 14 is formed on a lower surface of the encapsulant 13 and electrically connected to the semiconductor chips 12.

However, a position deviation easily occurs to the semiconductor chips due to expansion of the thermal release tape when being heated and impact of the mold flow during the molding process. As such, when a redistribution layer is formed subsequently, the redistribution layer cannot be aligned with and electrically connected to the semiconductor chips, thereby lowering the product reliability. Further, the use of the thermal release tape incurs a high fabrication cost.

Therefore, how to overcome the above-described disadvantages has become urgent.

### SUMMARY OF THE INVENTION

In view of the above-described drawbacks, the present invention provides a method for fabricating a semiconductor package, which comprises the steps of: providing a carrier having a release layer and an adhesive layer sequentially formed thereon; disposing a plurality of semiconductor chips on the adhesive layer; forming an encapsulant on the adhesive layer for encapsulating the semiconductor chips; and exposing the release layer to light through the carrier so as to remove the release layer and the carrier.

In an embodiment, the method further comprises forming a metal layer between the release layer and the adhesive layer.

After removing the release layer, the above-described method can further comprise removing the metal layer.

The metal layer can be 1 μm thick.

The above-described method can further comprise removing the adhesive layer. The metal layer and the adhesive layer can be removed by etching or a chemical method. The etching can be plasma etching or chemical etching.

In an embodiment, the method can further comprise, prior to exposing the release layer to light through the carrier, disposing a substrate on the encapsulant in a manner that the encapsulant is laminated therebetween.

In the above-described method, the adhesive layer can have a plurality of metal particles dispersed therein.

In the above-described method, the carrier can be made of glass.

In the above-described method, the substrate can be made of glass or silicon.

In the above-described method, the release layer can be made of amorphous silicon, parylene or α-SiO₂.

In the above-described method, the light can be laser light.

The above-described method can further comprise removing the substrate.

The above-described method can further comprise forming on the encapsulant a redistribution layer that is electrically connected to the semiconductor chips.

In the above-described method, the metal particles can be silicon oxide balls coated with metal.

In the above-described method, the laser light can have a wavelength of 532 nm.

In the above-described method, the adhesive layer can have a core copper layer and an adhesive film formed on two opposite surfaces of the core copper layer.

Therefore, by emitting light on the release layer to damage the release layer, the release layer and the carrier can be easily removed. Further, the metal layer, the adhesive layer having the metal particles dispersed therein or the adhesive layer having the core copper layer can be used to prevent the semiconductor chips and the encapsulant from being exposed to light so as to avoid any damage to the semiconductor chips and the encapsulant, thereby facilitating subsequent processes and increasing the product yield.

### BRIEF DESCRIPTION OF DRAWINGS

FIGS. 1A to 1E are schematic cross-sectional views illustrating a method for fabricating a semiconductor package according to the prior art;

FIGS. 2A to 2H are schematic cross-sectional views illustrating a method for fabricating a semiconductor package according to a first embodiment of the present invention;

FIG. 3 is a schematic cross-sectional view illustrating a method for fabricating a semiconductor package according to a second embodiment of the present invention;

FIG. 4 is a schematic cross-sectional view illustrating a method for fabricating a semiconductor package according to a third embodiment of the present invention;

FIG. 5 is a schematic cross-sectional view illustrating a method for fabricating a semiconductor package according to a fourth embodiment of the present invention; and

FIG. 6 is a schematic cross-sectional view illustrating a method for fabricating a semiconductor package according to a fifth embodiment of the present invention.

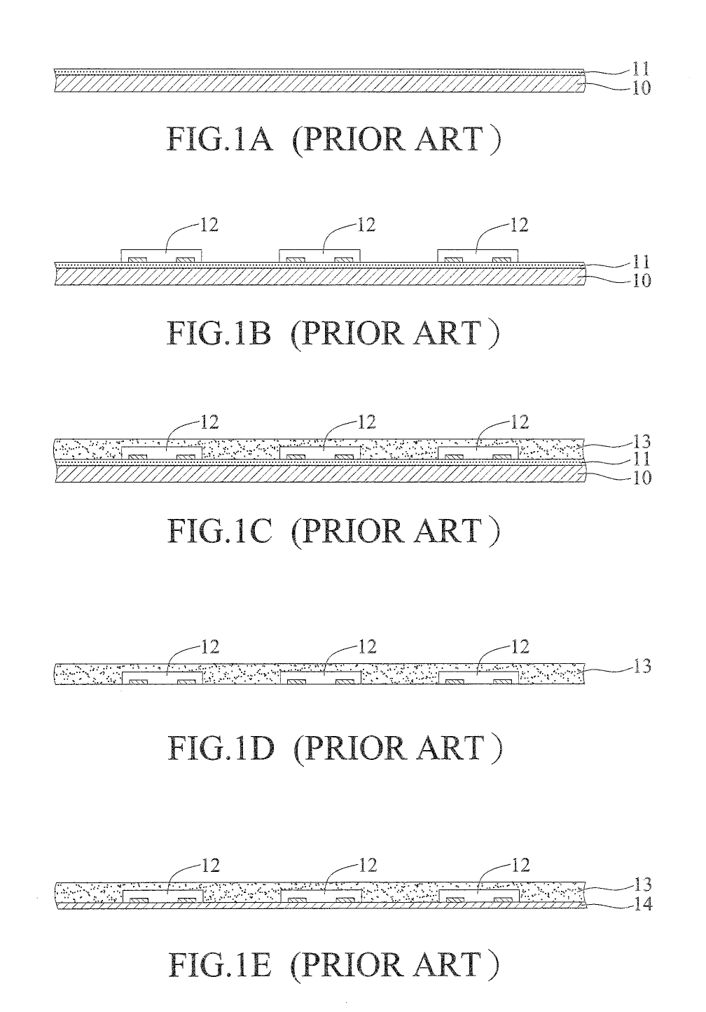

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “on”, “first”, “second” etc. are merely for illustrative purposes and should not be construed to limit the scope of the present invention.

### First Embodiment

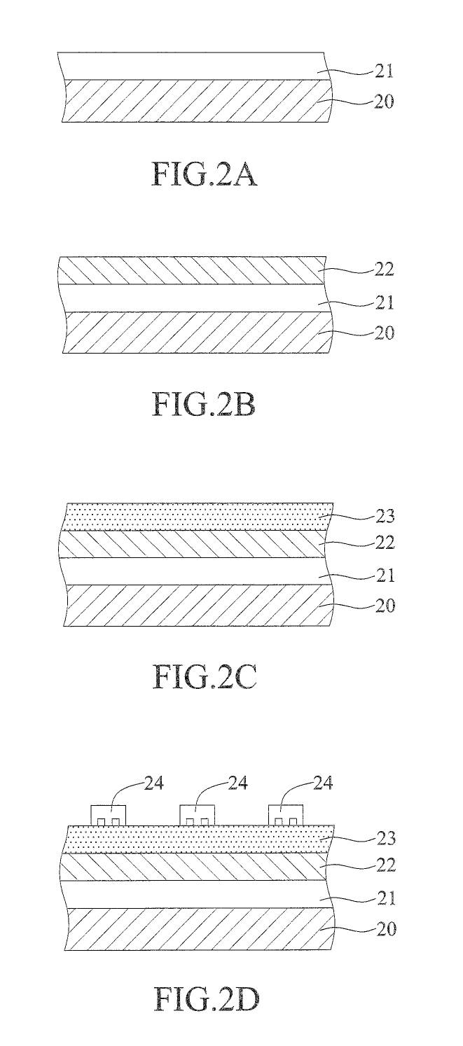

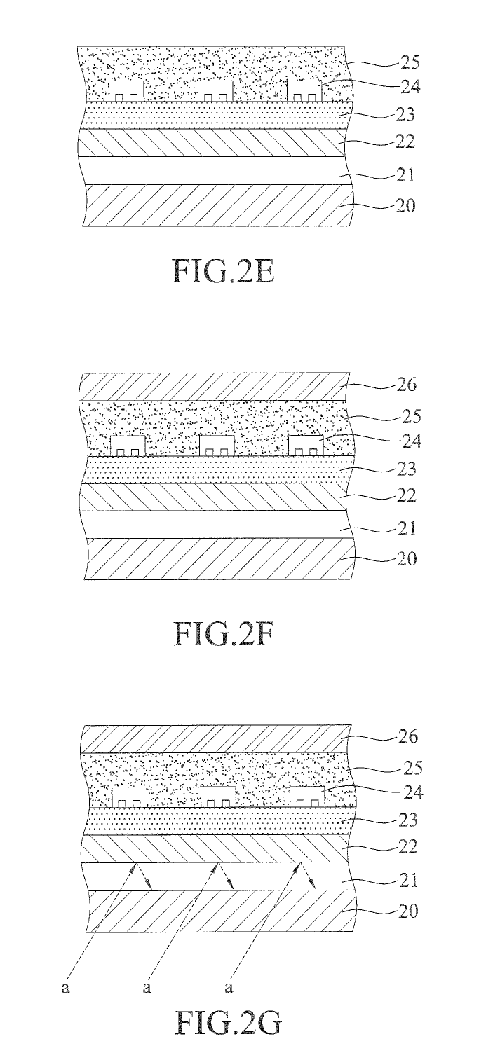

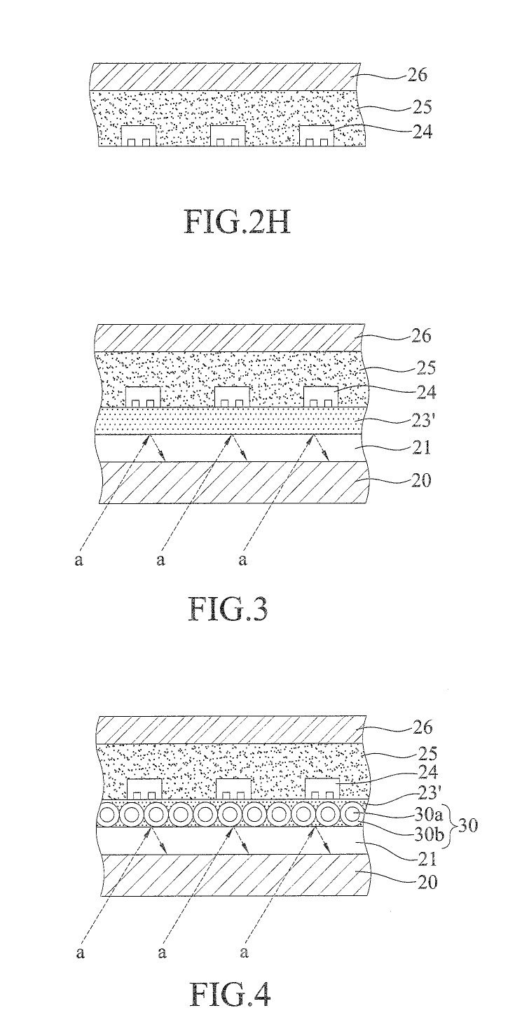

FIGS. 2A to 2H are schematic cross-sectional views illustrating a method for fabricating a semiconductor package according to a first embodiment of the present invention.

Referring to FIG. 2A, a carrier 20 is provided. The carrier 20 has a release layer 21 formed thereon. The carrier 20 can be made of glass. The release layer 21 can be made of amorphous silicon, parylene or α-SiO₂. The release layer 21 can be formed through a chemical vapor deposition (CVD) process.

Referring to FIG. 2B, a metal layer 22 is formed on the release layer 21 through PECVD (Plasma Enhance Chemical Vapor Deposition), CVD, PVD (Physical Vapor Deposition) or electroless plating. In the present embodiment, the metal layer 22 is 1 μm thick. The metal layer 22 can be made of any metal.

In an alternative embodiment, the metal layer 22 can be omitted.

Referring to FIG. 2C, an adhesive layer 23 is formed on the metal layer 22.

Referring to FIG. 2D, a plurality of semiconductor chips 24 are disposed on the adhesive layer 23 so as to be fixed by the adhesive layer 23 at certain positions. Each of the semiconductor chips 24 has a plurality of conductive pads and is disposed on the adhesive layer 23 with the conductive pads attached to the adhesive layer 23. The carrier can have a plurality of alignment marks to facilitate positioning the semiconductor chips 24 on the adhesive layer 23.

Referring to FIG. 2E, a molding process such as compression molding is performed to form an encapsulant 25 on the adhesive layer 23 so as to encapsulate the semiconductor chips 24. As such, the semiconductor chips 24 are protected by the encapsulant 25 from being contaminated, oxidized or damaged by external environment. Then, a curing process is performed to cure the encapsulant.

Referring to FIG. 2F, a substrate 26 is disposed on the encapsulant 25 in a manner that the encapsulant 25 is laminated therebetween. The substrate 26 can be made of glass or silicon.

Referring to FIG. 20, light a such as laser light is emitted through the carrier 20 towards the release layer 21. Particularly, a portion of the light a passes through the release layer 21. But the metal layer 22 prevents the adhesive layer 23, the semiconductor chips 24, and the encapsulant 25 from being exposed to the light and reflects a portion of the light a. In addition, the thickness of the metal layer 22 can be changed according to the power of the light a.

Referring to FIG. 2H, since the release layer 21 is exposed to and damaged by the light a, the release layer 21 and the carrier 20 can be easily removed. Then, the metal layer 22 and the adhesive layer 23 can be removed by etching, such as plasma etching or chemical etching, or a chemical method. Thereafter, the substrate 26 can be removed (if required) and a redistribution layer (not shown) can be formed on the encapsulant 25 and electrically connected to the semiconductor chips 24.

### Second Embodiment

FIG. 3 is a cross-sectional view illustrating a method for fabricating a semiconductor package according to a second embodiment of the present invention.

The present embodiment is similar to the first embodiment. A main difference of the present embodiment from the first embodiment is that the present embodiment dispenses with the metal layer 22 and instead forms an adhesive layer 23′ having a plurality of metal particles dispersed therein. The metal particles can prevent the light a from passing through the adhesive layer 23′.

### Third Embodiment

FIG. 4 is a cross-sectional view illustrating a method for fabricating a semiconductor package according to a third embodiment of the present invention.

The present embodiment is similar to the second embodiment. The present embodiment differs from the second embodiment in that the metal particles 30 are silicon oxide balls 30a coated with metal 30b. The metal particles 30 can prevent the light a from passing through the adhesive layer 23′.

### Fourth Embodiment

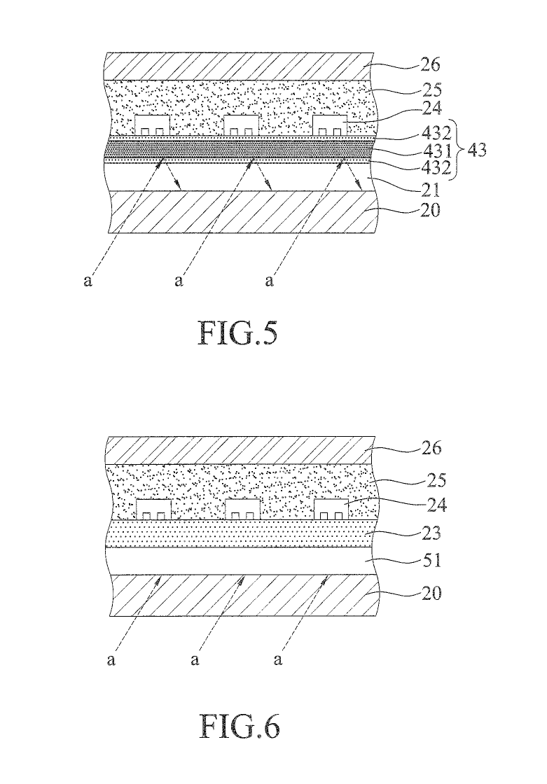

FIG. 5 is a cross-sectional view illustrating a method for fabricating a semiconductor package according to a fourth embodiment of the present invention.

The present embodiment is similar to the second embodiment. The present embodiment differs from the second embodiment in that the adhesive layer 43 (such as a copper adhesive tape) has a core copper layer 431 and an adhesive film 432 formed on two opposite surfaces of the core copper layer 431. The core copper layer 431 can prevent light a from passing through the adhesive layer 43.

### Fifth Embodiment

FIG. 6 is a cross-sectional view illustrating a method for fabricating a semiconductor package according to a fifth embodiment of the present invention.

The present embodiment is similar to the second embodiment. A main difference of the present embodiment from the second embodiment is that the release layer 51 is made of α-SiO₂ and formed through a CVD process and the light a is laser light with a wavelength at 532 nm. As such, when irradiated by the light a, the release layer 51 evaporates so as to be removed along with the carrier 20.

In addition, the metal particles in the adhesive layer 23 can be dispensed with. Instead, by adjusting the power of the light a, the release layer 51 can be damaged by the light a so as to be removed while the semiconductor chips 24 are not affected by the light a.

Therefore, by emitting light on the release layer to damage the release layer, the release layer and the carrier can be easily removed. Further, the metal layer, the adhesive layer having the metal particles dispersed therein or the adhesive layer having the core copper layer can be used to prevent the semiconductor chips and the encapsulant from being exposed to the light so as to avoid any damage to the semiconductor chips and the encapsulant, thereby facilitating subsequent processes and increasing the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method for fabricating a semiconductor package, comprising the steps of:
providing a carrier having a release layer and an adhesive layer sequentially formed thereon;
disposing a plurality of semiconductor chips on the adhesive layer;
forming an encapsulant on the adhesive layer for encapsulating the semiconductor chips; and
exposing the release layer to light through the carrier so as to remove the release layer and the carrier.

2. The method of claim 1, wherein the adhesive layer has a plurality of metal particles dispersed therein.

3. The method of claim 2, wherein the metal particles are silicon oxide balls coated with metal.

4. The method of claim 1, further comprising forming a metal layer between the release layer and the adhesive layer.

5. The method of claim 4, further comprising, after removing the release layer, removing the metal layer.

6. The method of claim 5, wherein the metal layer is removed by etching or a chemical method.

7. The method of claim 6, wherein the etching is plasma etching or chemical etching.

8. The method of claim 4, wherein the metal layer is 1 μm thick.

9. The method of claim 1, further comprising, prior to exposing the release layer to light, disposing a substrate on the encapsulant in a manner that the encapsulant is laminated therebetween.

10. The method of claim 9, wherein the substrate is made of glass or silicon.

11. The method of claim 9, further comprising removing the substrate.

12. The method of claim 1, further comprising removing the adhesive layer.

13. The method of claim 11, wherein the adhesive layer is removed by etching or a chemical method.

14. The method of claim 13, wherein the etching is plasma etching or chemical etching.

15. The method of claim 1, wherein the carrier is made of glass.

16. The method of claim 1, wherein the release layer is made of amorphous silicon, parylene, or α-SiO₂.

17. The method of claim 1, wherein the light is laser light.

18. The method of claim 17, wherein the laser light has a wavelength at 532 nm.

19. The method of claim 1, further comprising forming on the encapsulant a redistribution layer that is electrically connected to the semiconductor chips.

20. The method of claim 1, wherein the adhesive layer has a core copper layer and an adhesive film formed on two opposite surfaces of the core copper layer.
